(19) United States
(12) Patent Application Publication
(10) Pub. No.: US 2007/0241340 A1
(43) Pub. Date: Oct. 18, 2007

(54) Micro-mirror based display device having an improved light source

(76) Inventor: Shaoher X. Pan, San Jose, CA (US)

Correspondence Address: FISH & RICHARDSON P.C., PO BOX 1022, MINNEAPOLIS, MN, 55440-1022, US

(21) Appl. No.: 11/405,804

(22) Filed: Apr. 17, 2006

(51) Int. Cl. H01L 33/00; H01L 31/12; H01L 27/15; H01L 29/26

(52) U.S. Cl. 257/79

(57) ABSTRACT

A display device includes one or more light emitting diodes (LEDs) configured to emit light and a spatial light modulator comprising one or more tiltable micro mirrors each configured to receive the light emitted from the one or more LEDs and reflect the emitted light in two or more directions.

### BACKGROUND

The present disclosure relates to spatial light modulators.

In general, a micro mirror array is a type of spatial light modulator (SLM) that includes an array of cells, each of which includes a micro mirror that can be tilted about an axis and, furthermore, circuitry for generating electrostatic forces that can tilt the micro mirror plate. In a digital mode of operation, for example, there are two positions at which the micro mirror plate can be tilted. In an “on” position or state, the micro mirror plate directs incident light to an assigned pixel of a display device. In an “off” position or state, the micro mirror plate direct incident light away from the display device.

FIG. 1 is a schematic diagram of a conventional display device 100 implementing a micro mirror array. The display device 100 includes a spatial light modulator 110 mounted on a support plate 115, a light source system 130, a prism 140, and a projection lens 150. The spatial light modulator 110 includes an array of micro mirrors that can be tilted to different directions under electronic control. The light source system 130 includes an arc lamp 131, a condenser lens 132, a fold mirror 133, a UV/IR filter 134, a solid light pipe 135, a color wheel 136 mounted on a motor 137, a fold mirror 138, and a relay lens 139. The light emitted from the arc lamp 131 is reflected by a parabolic mirror to produce a collimated light beam 120. The collimated light beam 120 is directed by the condenser lens 132 and reflected by the fold mirror 133. The collimated light beam 120 then passes through the UV/IR filter 134 and then through the solid light pipe 135. The collimated light beam 120 then passes the spinning color filter 136. The color wheels include segments of red, green, and blue filters that can alternatively filter the collimated light beam 120 to different color light beams 121. The color light beam 121 is reflected by fold mirror 138 and then passes relay lens 139 to enter the prism 140. The color light beam 121 is reflected by an optical interface inside the prism 140 to illuminate the micro mirrors in the spatial light modulator 110. The micro mirrors can be tilted to an “on” position and an “off” position. The color light beams reflected by the mirrors at the “on” states are directed to the projection lens 150 for projecting an image on a screen.

### SUMMARY OF THE INVENTION

In a general aspect, the present invention relates to a display device including one or more light emitting diodes (LEDs) configured to emit light; and a spatial light modulator comprising one or more tiltable micro mirrors each configured to receive the light emitted from the one or more LEDs and reflect the emitted light in two or more directions.

In another general aspect, the present invention relates to a display device including one or more light emitting diodes (LEDs) configured to emit light; a spatial light modulator comprising one or more tiltable micro mirrors each configured to receive the light emitted from the one or more LEDs at two or more orientations to reflect the emitted light in two or more directions; and

one or more optical fibers configured to guide the light emitted from the one or more LEDs to the one or more micro mirrors.

In yet another general aspect, the present invention relates to a display device including a two-dimensional array of light emitting diodes (LEDs) each configured to emit light; a spatial light modulator comprising a two-dimensional array of tiltable micro mirrors each configured to receive the light emitted from the LEDs at two or more orientations to reflect the emitted light in two or more directions; and one or more optical fibers configured to guide the light emitted from the LEDs to the two-dimensional array of tiltable micro mirrors.

Implementations of the system may include one or more of the following. The one or more LEDs can be disposed in a two-dimensional array. The one or more tiltable micro mirrors can be tilted to two or more orientations reflect the emitted light in the two or more directions.

The one or more LEDs comprise LEDs capable of emitting lights of different colors. The one or more LEDs can include a red-light emitting LED, a green-light emitting LED, and a blue-light emitting LED. The display device can further include one or more optical fiber configured to guide the light emitted from the one or more LEDs to the one or more micro mirrors. The display device can further include a bundle of optical fibers each configured to guide the light emitted from one or the one or more LEDs to the one or more micro mirrors. The display device can further include a single optical fiber configured to guide the light emitted from the one or more LEDs to the one or more micro mirrors. At least one end of the optical fiber is coated with an anti-IR and/or anti-UV coating. At least one of the optical fiber includes a first end and a second end having a smaller diameter than the diameter of the first end. The light emitted from the array of LEDs can be received by the first end of the optical fiber and exits at the second end of the optical fiber. The display device can further include a prism configured to receive the light emitted by the array of LEDs and reflect the light to the one or more micro mirrors. The spatial light modulator can include a micro mirror having a mirror plate comprising a reflective upper surface, a lower surface, and a cavity having an opening on the lower surface; and a substrate comprising an upper surface, a hinge support post in connection with the upper surface, and a hinge component in connection with the hinge support post and the mirror plate, wherein the hinge component extends into the cavity to facilitate a rotation of the mirror plate.

Embodiments may include one or more of the following advantages. One problem with the current display device based on micro mirrors is associated the complex and expensive light source. The light source 130 includes a number of optical components and an arc lamp, which contributes to a significant portion of the system cost and manufacturing complexity to the display device. The arc lamp has a limited lifetime. An arc lamp can cost in the range $200 to $400 to replace, which cost represents a large consumerable expense for the micro-mirror based display devices. The disclosed system provides an improved light source for micro-mirror based display devices. The improved light source is based on an a plurality of (light emitting diodes) LEDs, which eliminate the costly arc lamp and a number of optical components such as solid light pipe, lenses, UV/IR filter, and a moving component the color wheel. As a result, the improved light source is of lower cost and more compact compared to the conventional light sources for micro-mirror based display devices.

Another advantage of the invention display system using the improved light source is that it can effectively provide a full color display. The red, green, and blue light emitting LEDs can be turned on and off to illuminate a single micro mirror array to produce the three color planes in an image without using a color wheel.

Yet another advantage of the invention display system is that the improved light source can provide greater brightness than does the arc lamp based light source. Furthermore, the LEDs are more energy efficient and have much longer life time, which can significantly reduce the expenses for the users.

Another drawback with the lamp modules of the conventional optical projectors is in the high operation electrical voltage for the arc lamp. Since the operation electrical voltage can be greater than 10,000 volts, an improper use of the projector can present a danger of electrical shock. The disclosed invention system uses low voltage power supply for the LEDs and thus removes a safety issue associated with the arc lamp in the conventional projection display devices.

Although the invention has been particularly shown and described with reference to multiple embodiments, it will be understood by persons skilled in the relevant art that various changes in form and details can be made therein without departing from the spirit and scope of the invention.

### BRIEF DESCRIPTION OF THE DRAWINGS

The following drawings, which are incorporated in and from a part of the specification, illustrate embodiments of the present invention and, together with the description, serve to explain the principles of the invention.

FIG. 1 illustrates a schematic diagram of a micro-mirror based display device in the prior art.

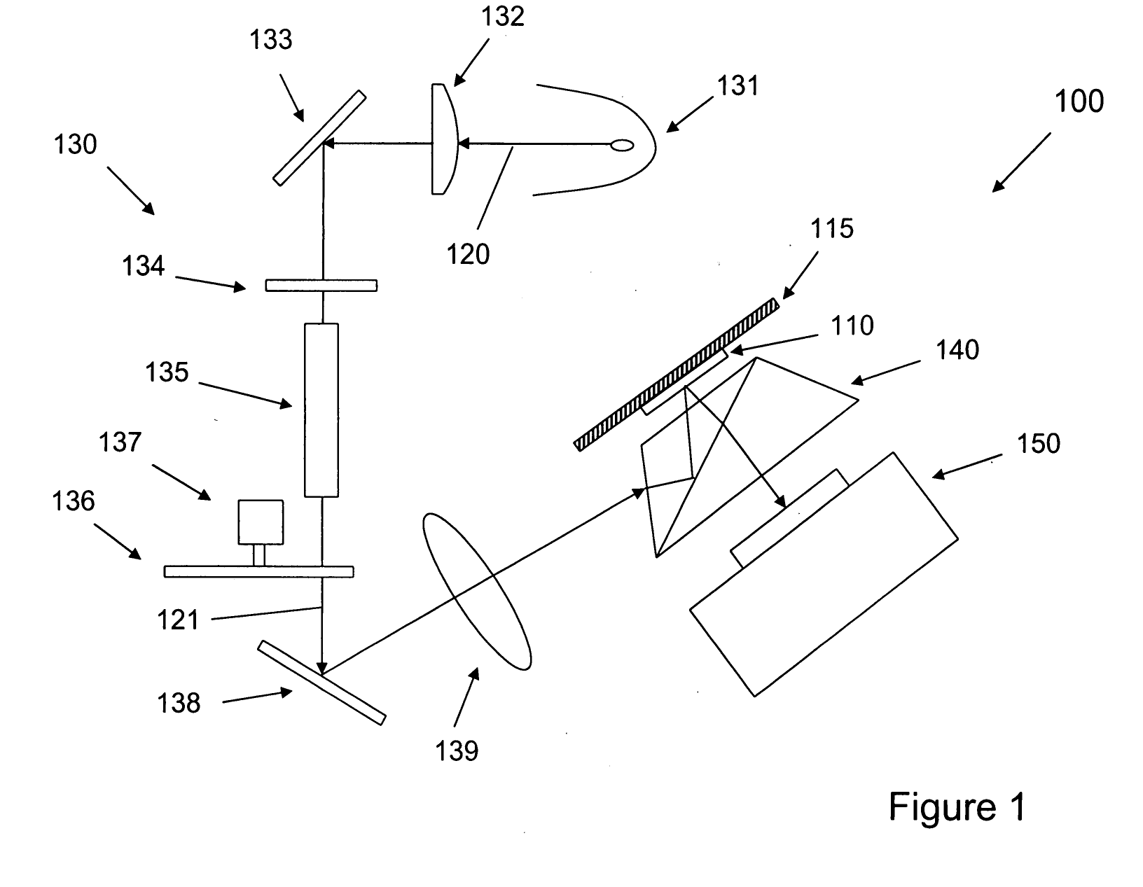

FIG. 2 is a schematic diagram of a micro-mirror based display system having an improved light source in accordance with the present invention.

### DETAILED DESCRIPTION

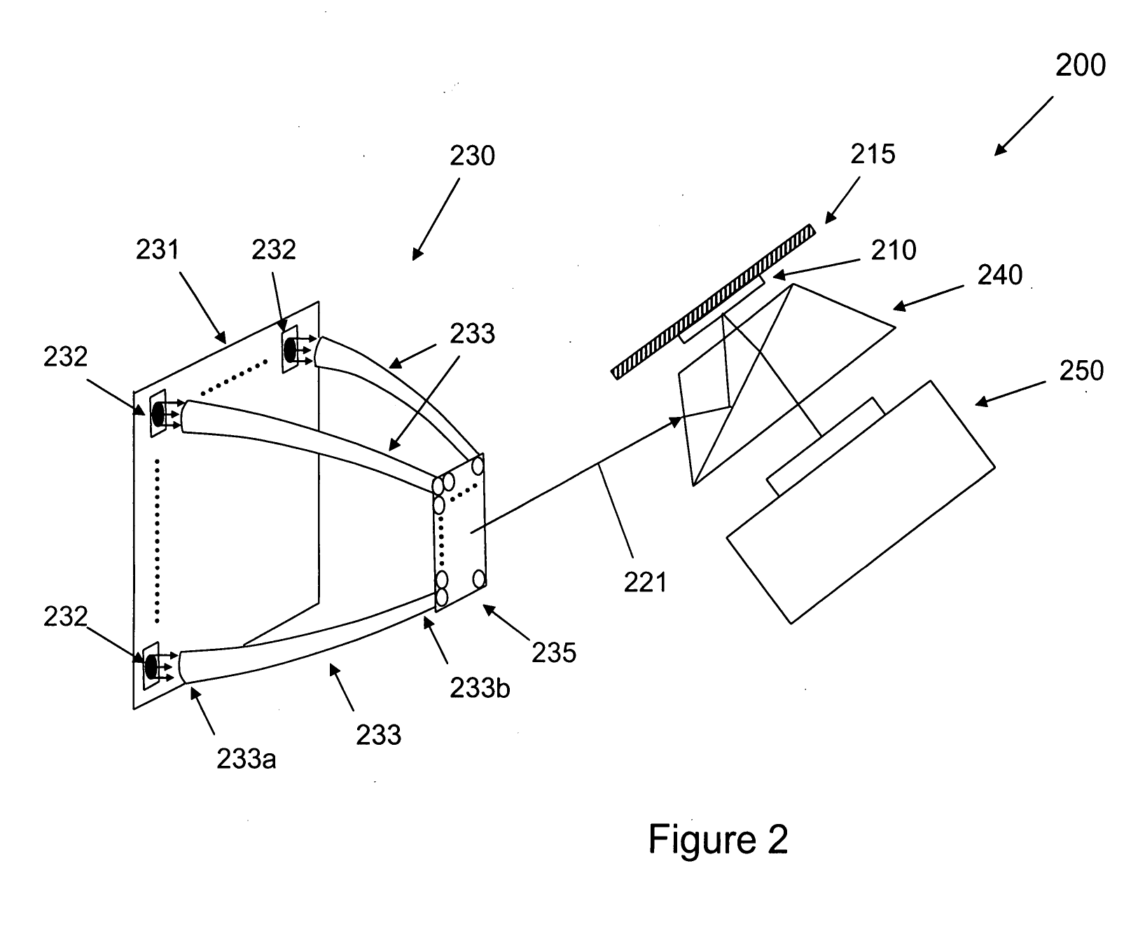

FIG. 2 is a schematic diagram of a micro-mirror based display system 200 having an improved light source 230 in accordance with the present invention. The display system 200 includes a spatial light modulator 210 mounted on a support panel 215, a light source system 230, and a prism 240. The spatial light modulator 210 includes an array of micro mirrors that can be tilted to two or more orientations under electronic control.

In one embodiment, the micro mirror in the spatial light modulator 210 includes a mirror plate and a substrate. The mirror plate includes a reflective upper surface, a lower surface, and a a cavity having an opening on the lower surface. The substrate includes an upper surface, a hinge support post in connection with the upper surface, and a hinge component in connection with the hinge support post and the mirror plate. The hinge component extends into the cavity to facilitate a rotation of the mirror plate. The micro mirrors can be tilted in two or more orientations under the control of electronic signals. A suitable array of the micro mirrors is described in the commonly assigned U.S. patent application Ser. No. 10/974,468, titled “High contrast spatial light modulator and method”, filed Oct. 27, 2004, and U.S. patent application Ser. No. 10/974,461, titled “High contrast spatial light modulator”, filed Oct. 26, 2004, the contents of which are incorporated herein by reference.

The improved light source system 230 includes a LED array 231 comprising a plurality of LEDs 232. The LEDs 232 can be disposed in a two dimension array mounted on a substrate. The light emitted from the LEDs 232 can be combined as a single light illumination to the micro mirrors in the display system 200. The number of LEDs 232 in the two dimensional array can be flexibly varied to provide optimal illumination brightness for the display system 200. There is therefore not a limitation in the maximum brightness as is the case with the arc lamp 131 in the conventional display device 100. The improved light source system 230 also includes one or more optical fibers 233 that can guide the light emitted from the LEDs 232 to a compact light emitting array 235. The light beam 221 emitted from the light emitting array 235 is directed to enter the prism 240. The light beam 221 is reflected by an optical interface inside the prism 240 to illuminate the micro mirrors in the spatial light modulator 210. The color light beams deflected by the mirrors oriented at the “on” position are directed to the projection lens 250 for projecting an image on a screen.

In one embodiment, each LED 232 in the LED array 231 is coupled with an optical fiber 233. A plurality of optical fibers 233 can be coupled to the LEDs 232 in the LED array 231. The optical fiber 233 can have a substantially uniform width along its length. The optical fiber 233 can also include a larger end 233a and smaller end 233b, which make it easier for coupling the light emitted from the LED 232 and allowing a more compact light emitting array 235.

In another embodiment, a single optical fiber can be used to guide the light emitted from the LEDs 232 in the LED array 231 to produce a beam to enter the prism 240. Whether a single or a plurality of optical fiber is used in the improved light source system 230 can be determined by the number of LEDs 232 required in the display system 200.

A thin-film of a UV- or IR-absorbing material can be coated at one or both ends of the optical fibers 233 to absorb UV or IR lights, which eliminates the needs for separate IR/UV filters 134 in the conventional display device 100. Examples of such coating materials are described in U.S. Pat. Nos. 5,959,012, 6,001,755, and 6,191,884.

An advantageous feature of the display system 200 is that the LEDs 232 can emit red, green, and blue lights. Red, green, and blue light emitting LEDs can be sequentially turned on and off to illuminate the spatial light modulator 210 to produce the three color planes in an image without using a color wheel. The relative brightness of the different color planes can be adjusted by the durations of the illumination of each color LEDs or by the number of each color LEDs in the LED array 231.

It is understood that the disclosed systems and methods are compatible with other configurations of LEDs, optical fibers, and the micro mirrors. The micro mirrors can generally include mirrors that are made by micro-fabrication techniques and that can be tilted in one or more orientations under electronic control. Light emitting diodes can emit coherent (laser) and non-coherent light sources that can exist in different configurations and dimensions. The configurations of optical fibers are also not limited to what described above. Many different types of optical fibers can be used to guide the light emitted by the LEDs to the micro mirrors. Different types of optical systems can be used to transmit the light from the LEDS to the micro mirrors and from the micro mirrors to the image display. The optical systems are not limited to the prism and the projection lens described above.

What is claimed is:

1. A display device, comprising:
one or more light emitting diodes (LEDs) configured to emit light; and
a spatial light modulator comprising one or more tiltable micro mirrors each configured to receive the light emitted from the one or more LEDs and reflect the emitted light in two or more directions.

2. The display device of claim 1, wherein the one or more LEDs are disposed in a two-dimensional array.

3. The display device of claim 1, wherein the one or more tiltable micro mirrors can be tilted to two or more orientations reflect the emitted light in the two or more directions.

4. The display device of claim 1, wherein the one or more LEDs comprise LEDs capable of emitting lights of different colors.

5. The display device of claim 4, wherein the one or more LEDs include a red-light emitting LED, a green-light emitting LED, and a blue-light emitting LED.

6. The display device of claim 1, further comprising:
one or more optical fiber configured to guide the light emitted from the one or more LEDs to the one or more micro mirrors.

7. The display device of claim 6, further comprising:
a bundle of optical fibers each configured to guide the light emitted from one or the one or more LEDs to the one or more micro mirrors.

8. The display device of claim 6, further comprising:
a single optical fiber configured to guide the light emitted from the one or more LEDs to the one or more micro mirrors.

9. The display device of claim 6, wherein at least one end of the optical fiber is coated with an anti-IR and/or anti-UV coating.

10. The display device of claim 6, wherein at least one of the optical fiber includes a first end and a second end having a smaller diameter than the diameter of the first end.

11. The display device of claim 10, wherein the light emitted from the array of LEDs is received by the first end of the optical fiber and exits at the second end of the optical fiber.

12. The display device of claim 1, further comprising:
a prism configured to receive the light emitted by the array of LEDs and reflect the light to the one or more micro mirrors.

13. The display device of claim 1, wherein the spatial light modulator comprises
a micro mirror having a mirror plate comprising a reflective upper surface, a lower surface, and a cavity having an opening on the lower surface; and
a substrate comprising an upper surface, a hinge support post in connection with the upper surface, and a hinge component in connection with the hinge support post and the mirror plate, wherein the hinge component extends into the cavity to facilitate a rotation of the mirror plate.

14. A display device, comprising:
one or more light emitting diodes (LEDs) configured to emit light;
a spatial light modulator comprising one or more tiltable micro mirrors each configured to receive the light emitted from the one or more LEDs at two or more orientations to reflect the emitted light in two or more directions; and
one or more optical fibers configured to guide the light emitted from the one or more LEDs to the one or more micro mirrors.

15. The display device of claim 14, wherein the one or more LEDs are disposed in a two-dimensional array.

16. The display device of claim 14, wherein the one or more LEDs include LEDs capable of emitting lights of different colors.

17. The display device of claim 16, wherein the one or more LEDs include a red-light emitting LED, a green-light emitting LED, and a blue-light emitting LED.

18. The display device of claim 14, further comprising:
a bundle of optical fibers each configured to guide the light emitted from one or the one or more LEDs to the one or more micro mirrors.

19. The display device of claim 14, further comprising:
a single optical fiber configured to guide the light emitted from the one or more LEDs to the one or more micro mirrors.

20. The display device of claim 14, wherein at least one of the optical fiber includes a first end and a second end having a smaller diameter than the diameter of the first end.

21. The display device of claim 20, wherein the light emitted from the array of LEDs is received by the first end of the optical fiber and exits at the second end of the optical fiber.

22. The display device of claim 14, wherein the spatial light modulator comprises
a micro mirror having a mirror plate comprising a reflective upper surface, a lower surface, and a cavity having an opening on the lower surface; and
a substrate comprising an upper surface, a hinge support post in connection with the upper surface, and a hinge component in connection with the hinge support post and the mirror plate, wherein the hinge component extends into the cavity to facilitate a rotation of the mirror plate.

23. A display device, comprising:
a two-dimensional array of light emitting diodes (LEDs) each configured to emit light;
a spatial light modulator comprising a two-dimensional array of tiltable micro mirrors each configured to receive the light emitted from the LEDs at two or more orientations to reflect the emitted light in two or more directions; and
one or more optical fibers configured to guide the light emitted from the LEDs to the two-dimensional array of tiltable micro mirrors.
